(19) United States
(12) Patent Application Publication
(10) Pub. No.: US 2008/0105970 A1
(43) Pub. Date: May 8, 2008

(54) Vertical Integration of Passive Component in Semiconductor Device Package for High Electrical Performance

(76) Inventor: Shinichi Togawa, Kanagawa (JP)

Correspondence Address: Yisheng Tung;Texas Instruments Incorporated, M/S 3999, P.O. Box 655474, Dallas, TX, 75265, US

(21) Appl. No.: 11/679,173

(22) Filed: Feb. 26, 2007

Related U.S. Application Data
(60) Provisional application No. 60/863,999, filed on Nov. 2, 2006.

(51) Int. Cl. H01L 23/043; H01L 21/58

(52) U.S. Cl. 257/724; 438/107; 257/E23.183; 257/E21.505

(57) ABSTRACT

A high performance package and methods for its assembly are disclosed. A semiconductor package system of the invention is assembled in a method including the steps of affixing one or more spacers to a package substrate and affixing one or more passive components to the substrate adjacent to the spacers in order to define a plane. A semiconductor chip is affixed in the plane atop the one or more passive components and spacers and is electrically coupled to the one or more passive components.

### PRIORITY ENTITLEMENT

This application claims priority based on Provisional Patent Application Ser. No. 60/863,999 filed on Nov. 2, 2006, which is incorporated herein for all purposes by this reference. This application and the Provisional Patent Application have a common inventor and are assigned to the same entity.

### TECHNICAL FIELD

The invention relates to electronic semiconductor devices and manufacturing. More particularly, the invention relates to microelectronic semiconductor assemblies having vertically stacked ICs (integrated circuits) and passive circuit components contained within a single package and to methods related to the manufacture of such package systems.

### BACKGROUND OF THE INVENTION

It is often desirable to include passive components in a semiconductor device package to work in concert with a more complex IC. Commonly, one or more passive components, such as capacitors for example, are mounted on a substrate, such as a PCB (printed circuit board), adjacent to the IC. The passive components and IC are typically operably coupled using conductive traces in the PCB. In this way, input or output signals to or from the IC can be managed and controlled.

There is generally an ongoing need to minimize the size of electronic apparatus. At the same time, the demand for increased features results in an increase in the number of components on a given device. Efforts are continuously being made to design and manufacture devices with reduced area, but attempts to increase density while reducing area eventually reach a practical limit. In systems using passive components mounted adjacent to a more sophisticated, active, and relatively larger IC, it is known to reduce area by minimizing the area of the IC itself, minimizing the area occupied by the passive components, and minimizing the area occupied by the interconnecting conductive traces in the substrate.

In addition to the need for a reduction in the area occupied by ICs and associated passive components, other related problems concern performance. It is generally beneficial to keep the length of traces between ICs and passive components to a minimum in order to reduce or eliminate performance problems such as propagation delays and timing jitter, parasitic capacitance, and the potential for interference. Minimizing trace length can also improve the SNR (signal-to-noise ratio), and reduce the INL (integral non-linearity), of the circuitry.

Due to these and other technical challenges, improved semiconductor package systems with reduced area and enhanced performance capabilities, and related methods for their manufacture, would be useful and advantageous in the arts. The present invention is directed to overcoming, or at least reducing the effects of one or more of the problems noted above.

### SUMMARY OF THE INVENTION

In carrying out the principles of the present invention, in accordance with preferred embodiments thereof, the invention provides vertically integrated semiconductor package assemblies and methods for their manufacture.

According to one aspect of the invention, a method for assembling a semiconductor package system includes steps for affixing one or more spacer and one or more passive component adjacent to one another on the package substrate. A semiconductor chip is affixed in a plane atop the spacer and passive components and is electrically connected to the passive components.

According to another aspect of the invention, a semiconductor device package of a preferred embodiment includes a package substrate with one or more attached spacer. One or more passive components are affixed to the substrate adjacent to the one or more spacers in an arrangement wherein a semiconductor chip is affixed in a plane atop the spacer(s) and the passive component(s).

According to another aspect of the invention, one or more capacitor is affixed to a substrate adjacent to at least one spacer in a configuration for receiving an overlying semiconductor chip mounted atop the capacitor and spacer.

According to another aspect of the invention, one or more passive components is affixed to a substrate adjacent to at least one spacer comprising an IC in a configuration for receiving an overlying semiconductor chip mounted atop the capacitor and spacer.

According to another aspect of the invention, a preferred embodiment of a semiconductor device package having a semiconductor chip mounted on one or more spacer and one or more passive components is configured as a BGA (ball grid array) package.

According to yet another aspect of the invention, according to a preferred embodiment, a number of passive components are affixed to a substrate on more than one side of a spacer and a semiconductor chip is mounted on the plane defined by the surface of the spacer and adjacent passive components.

According to still another aspect of the invention, a semiconductor device package includes a spacer having a niche for receiving one or more passive components affixed to the substrate therein. A semiconductor chip is mounted over the spacer and one or more passive components.

The invention has advantages including but not limited to one or more of the following: providing manufacturing methods for high-performance semiconductor device package systems; providing package assemblies having reduced area; reduced susceptibility to noise; improved performance; and reduced manufacturing costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view of an example of a preferred embodiment of a semiconductor package system according to the invention;

FIG. 2 is a top view of the example shown in FIG. 1 of a preferred embodiment of a semiconductor package system according to the invention;

FIG. 3 is a top view of an example of a preferred embodiment of a semiconductor package system according to the invention;

FIG. 4 is a top view of an example of a preferred embodiment of a semiconductor package system according to the invention;

FIG. 5 is a top view of an example of an alternative embodiment of a semiconductor package system according to the invention;

FIG. 6 is a top view of a further example of another alternative embodiment of a semiconductor package system according to the invention; and

FIG. 7 is a simplified process flow diagram illustrating steps according to a preferred embodiment of a method of the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

The invention provides high-performance semiconductor package systems and methods related to their manufacture. The vertical integration of passive circuit components into packages which also include more sophisticated ICs provides package systems having a reduced overall footprint and superior electrical performance.

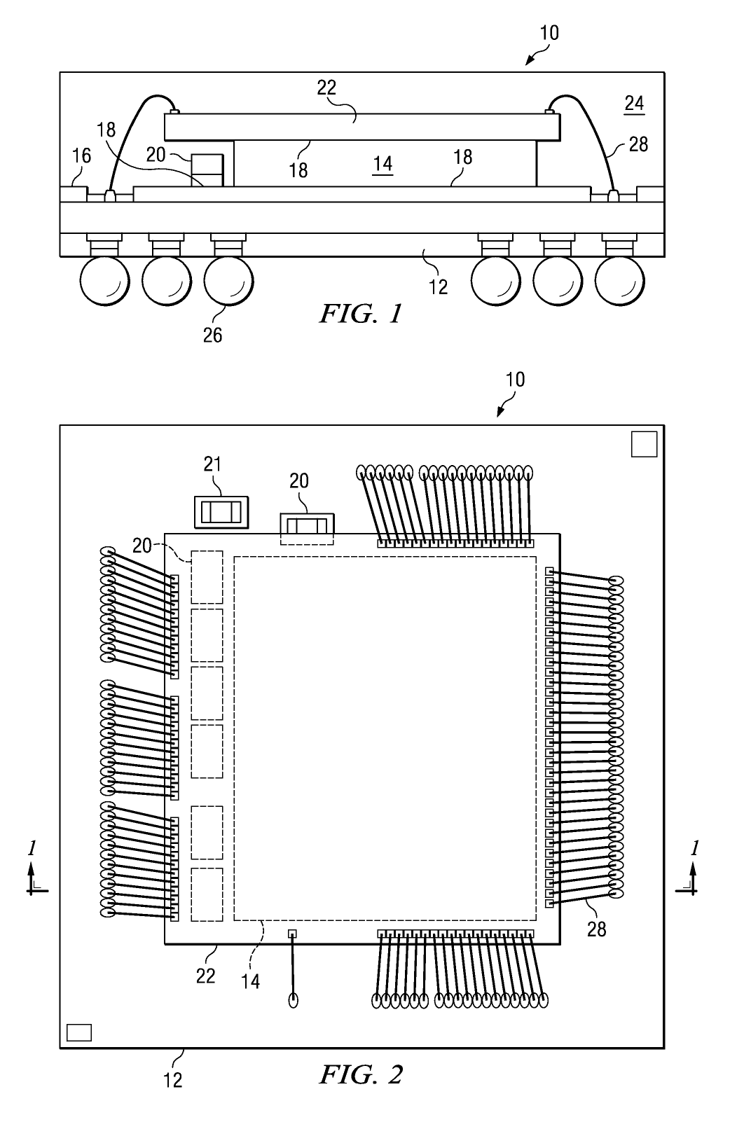

First referring primarily to FIG. 1, a cutaway side view shows an exemplary embodiment of a semiconductor device package system 10 of the invention. A substrate 12 such as a multi-layer PCB suitable for a fine pitch PBGA for example, is shown with a spacer 14 affixed to one of its surfaces 16 with die attach material 18 such as die attach film or curable die attach adhesive known in the arts. Adjacent to the spacer 14, one or more passive circuit components 20 are affixed to the substrate 12 surface 16, preferably using similar or identical die attach material 18. A chip 22, preferably an integrated circuit relatively large and complex relative to the passive circuit component 20, is affixed to the exposed surface of the spacer 14 and also extends over the passive circuit component 20. As shown, the spacer 14 and the adjacent passive component 20 on the substrate 12 provide a planar area suitable for mounting the chip 22. The chip 22 is preferably attached using die attach material 18 similar to that used for the spacer 14 and passive circuit component(s) 20. It should be appreciated that the area of the chip 22 is greater than the combined area of the spacer 14 plus at least a portion of one or more underlying passive circuit components 20. Accordingly, the chip 22 and at least a portion of a passive circuit component 20 occupy a total area less than the sum of the area of the chip 22 and the area of a passive circuit component 20. Preferably, the system 10 is encased in a suitable encapsulant 24 such as resin, plastic, or epoxy mold compound in order to protect it from the elements as is familiar in the arts. Additionally, solder balls 26 may preferably be provided at the substrate 12 as is commonly practiced in the art. Wirebonds 28 may also be provided in order to form operable connections between the chip 22 and contacts located on the substrate 12.

A top view corresponding to the preferred embodiment of a package system 10 of the invention shown in FIG. 1 is depicted, with encapsulant (24 in FIG. 1) omitted for the sake of the illustration, in FIG. 2. It can be seen that the passive circuit components 20 of the package system 10 occupy an area on the PCB 12 beneath the chip 22. Also shown in this example of a preferred embodiment of the invention, the chip 22, PCB 12, and passive circuit components 20 may be operably connected using wirebonds 28 in a manner familiar in the arts. Of course, additional passive circuit components 21 may also be included outside of the area overlain by the chip 22 without departure from the invention.

Preferably the material of the spacer 14 and surrounding material, e.g. the passive components 20, chip 22, substrate 12, and encapsulant 24, have similar thermal properties in order to avoid temperature-induced stress among the components of the package system 10. Preferably, the spacer 14 has a Coefficient of Thermal Expansion (CTE) as close as reasonably practical to the CTE of the surrounding package components. For embodiments in which the spacer is inert, the spacer material 14 is preferably selected for its thermal and mechanical, and not electrical, properties. A variety of materials may be used, such as plastic, epoxy, or ceramic, for example. In alternative embodiments, an IC may be used as a spacer. In the preferred embodiment shown and described, the spacer material 14 is preferably a solid body suitable for placement on the substrate in a manner similar to chip placement, although alternatively a curable material may be used to form a rigid spacer in position on the substrate. Numerous individual spacers and passive components may be used without departure from the invention and the spacer(s) and passive component(s) may be affixed to the PCB in any order. It should also be appreciated by those skilled in the arts that mounting a chip in a plane defined by underlying spacers and passive components reduces the area of the overall assembly, which may provide performance benefits, for example as a result of reducing the length of electrical paths within the assembly. Further advantages for some applications include the potential for adding capacitors to circuitry while nevertheless realizing a diminished footprint. Using a preferred embodiment as shown, for example, the number of capacitors included with a packaged BGA may be increased, resulting in improved SNR and INL, as well as a smaller footprint.

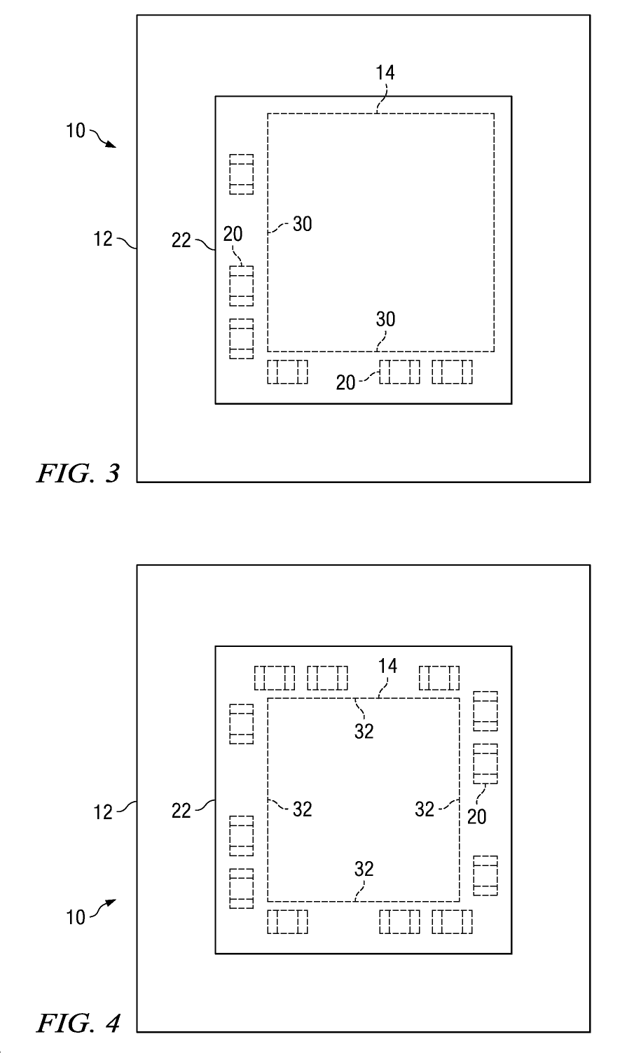

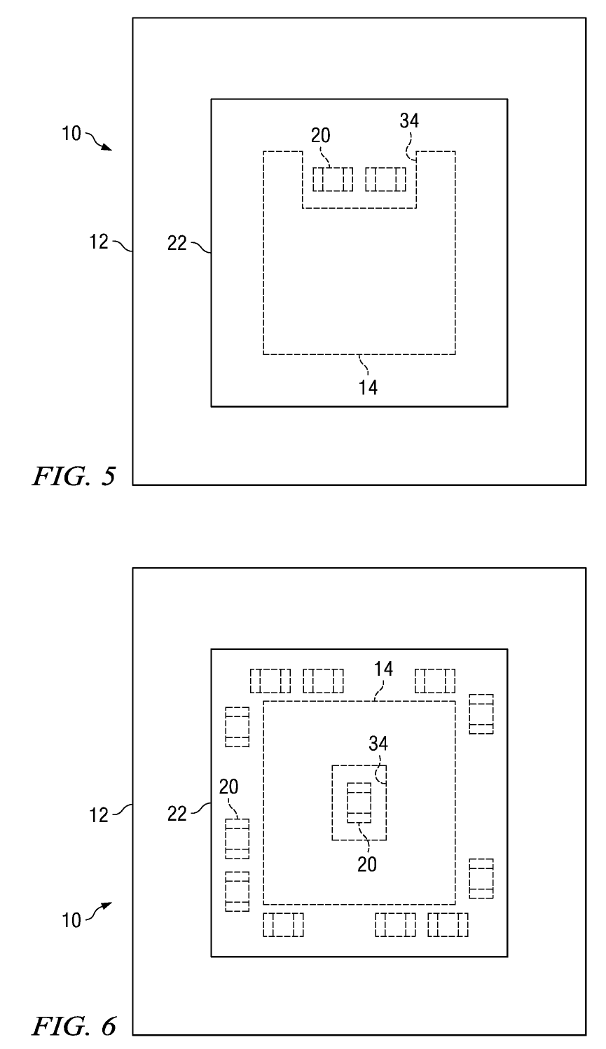

The possible variations within the scope of the invention are numerous and cannot all be shown. It should be understood that the top views shown in FIGS. 3 through 6 are provided in order to illustrate examples representative of alternative configurations of the invention. Thus, features such as encapsulant and wirebonds, though typically present, have been omitted from the drawings for the purpose of maintaining simplicity in depicting examples of possible implementations of the invention. An example of an alternative embodiment of the invention is depicted in FIG. 3. A top view of a semiconductor package system 10 is shown in which a chip 22 overlays a spacer 14 and a number of passive circuit components 20. The passive circuit components 20 are arranged along more than one edge 30 of the spacer 14, in this case two edges 30. It can be seen in this example that the practice of the invention is not limited to configurations wherein the passive circuit components are positioned adjacent to one edge 30 of a spacer 14 only. Another alternative embodiment of a semiconductor package system 10 according to the invention is shown in FIG. 4, illustrating a configuration in which passive circuit components 20 surround the entire periphery 32 of a spacer 14. FIG. 5 and FIG. 6 depict further alternative embodiments of semiconductor package systems 10 in which a spacer 14 includes a niche 34 suitable for placement of one or more passive components 20. These exemplary embodiments are representative of alternative implementations of the principles of the invention using variations in shape, area, number of components, size, etc., and are not intended to be an exhaustive listing of each and every possible variation within the scope of the invention. It should also be noted that in any implementation, underfill material or dielectric encapsulant may also be used to eliminate gaps between or among components of the assembly 10 as generally practiced in the semiconductor packaging arts. Additionally, manufacturing steps including but not limited to grinding, sawing, underfilling, molding, marking, testing, cleaning, film attachment, ball attachment, and singulation may be performed as generally known in the arts in various combinations without significantly departing from the practice of the invention.

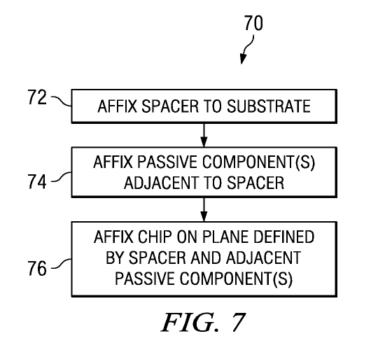

An alternative view of the steps of preferred methods of the invention is shown in the simplified process flow diagram of FIG. 7. A preferred method for assembling a semiconductor package system 70 of the invention includes affixing at least one spacer to a package substrate 72. A substrate suitable for a BGA may preferably be used for example, with a spacer affixed to its surface with die attach film or curable die attach adhesive. The spacer material is preferably selected for thermal and mechanical compatibility with the substrate. Although a solid spacer body is preferred for pick-and-place deployment on the substrate, alternatively a curable material may be used to form a spacer in place. In another step shown at box 74, one or more passive components is attached to the substrate in a location adjacent to the location of the spacer, preferably using die attach material similar to that used for attaching the spacer. The passive component may be any passive circuit element required for the particular application such as a capacitor, inductor, or resistor. A semiconductor chip is affixed 76 atop the spacer and the one or more passive components. Preferably, the spacer(s) and the adjacent passive component(s) on the substrate more or less define a plane suitable for mounting a semiconductor chip using typical die attach material. Preferably, the semiconductor chip is then electrically coupled to the one or more passive components for operation in concert. It should be understood that the area of the chip is greater than the combined area of the spacer plus at least a portion of one or more underlying passive circuit components, resulting in an overall reduced footprint of the system compared to a side-by-side arrangement. Additional steps may be performed without departure from the invention. For example, wirebonds may generally be provided in order to form operable electrical connections between the chip and contacts located on the substrate for that purpose. Typically, the system is also encased in a suitable encapsulant in order to complete the protective package. Solder may also be provided at the exposed surface of the substrate to facilitate interconnection with additional circuitry.

The methods and systems of the invention provide one or more advantages including but not limited to reducing the planar area occupied by packaged semiconductor device systems and improving performance characteristics. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

I claim:

1. A method for assembling a semiconductor package system comprising the steps of:
affixing one or more passive components to a package substrate;
affixing one or more spacers to the substrate adjacent to one or more passive components;
whereby the top surfaces of the passive components and adjacent spacers provide a planar area for receiving a semiconductor chip above the plane of the substrate; and
affixing a semiconductor chip in the planar area atop the passive components and spacers, and electrically coupling the semiconductor chip to the one or more passive components.

2. A method according to claim 1 wherein the step of affixing one or more passive components to the substrate further comprises affixing a capacitor to the substrate.

3. A method according to claim 1 wherein the step of affixing one or more passive components to the substrate further comprises affixing an inductor to the substrate.

4. A method according to claim 1 wherein the step of affixing one or more passive components to the substrate further comprises affixing a resistor to the substrate.

5. A method according to claim 1 wherein the step of affixing one or more spacers to the substrate further comprises affixing an IC to the substrate.

6. A semiconductor device package comprising:
a package substrate;
one or more spacers affixed to the substrate;
one or more passive components affixed to the substrate adjacent to the one or more spacers;
whereby the top surfaces of the spacers and adjacent passive components provide a planar area for receiving a semiconductor chip above the plane of the substrate; and
a semiconductor chip affixed in the planar area atop the spacers and passive components.

7. A semiconductor device package according to claim 6 wherein the semiconductor chip is electrically coupled to the one or more passive components.

8. A semiconductor device package according to claim 6 wherein the one or more passive components comprises a capacitor.

9. A semiconductor device package according to claim 6 wherein the one or more passive components comprises an inductor.

10. A semiconductor device package according to claim 6 wherein the one or more passive components comprises a resistor.

11. A semiconductor device package according to claim 6 wherein one or more spacer further comprises an IC operably coupled to the substrate.

12. A semiconductor device package according to claim 6 wherein the package substrate comprises a ball grid array package substrate.

13. A semiconductor device package according to claim 6 wherein the package substrate comprises a fine pitch ball grid array package substrate.

14. A semiconductor device package according to claim 6 wherein a plurality of passive components are affixed to the substrate on more than one side of a spacer.

15. A semiconductor device package according to claim 6 wherein a plurality of passive components are affixed to the substrate around the periphery of a spacer.

16. A semiconductor device package according to claim 6 wherein a spacer further comprises a niche, and wherein one or more passive component is affixed to the substrate within the niche of the spacer.
